(19) United States
(12) Patent Application Publication
(10) Pub. No.: US 2026/0128068 A1
(43) Pub. Date: May 7, 2026

(54) MEMORY DEVICE COMPRISING AN ARRAY OF MEMORY CELLS

(71) Applicant: Commissariat à l'Energie Atomique et aux Energies Alternatives, Paris (FR)

(72) Inventors: Thomas BAUVENT, Grenoble (FR); Gaël PILLONNET, Grenoble (FR); Gabriel MOLAS, Grenoble (FR)

(21) Appl. No.: 19/376,914

(22) Filed: Nov. 1, 2025

(30) Foreign Application Priority Data
Nov. 5, 2024 (FR) 2412063

(51) Int. Cl. G11C 5/06; G11C 13/00

(52) U.S. Cl. CPC G11C 5/063; G11C 13/0038; G11C 13/004; G11C 13/0069; G11C 13/0097

(57) ABSTRACT

A memory device (100) comprising an array of memory cells (102.1-102.4) each comprising M memory elements (106) and a switch (104), the memory cells being addressed by word lines (108), source lines (112) and bit lines (110), wherein: a first conduction electrode of each switch is coupled to a first electrode of each of the memory elements of a single one of the memory cells; each word line is coupled to a control electrode of each switch of a single and same column of memory cells; each source line is coupled to a second conduction electrode of each switch of a single and same row of memory cells; each bit line is coupled to a second electrode of one of the memory elements of each memory cell of a single and same column of memory cells.

### FIELD

The present disclosure relates generally to the field of electronic devices having an array of memory cells, including in particular resistive memory elements (known as RRAM or ReRAM for “Resistive Random-Access Memory”), for example based on oxide (of the OxRAM type for “Oxide-based Random-Access Memory”) or on a metal electrolyte (of the CBRAM type for “Conductive-Bridging Random-Access Memory”), or magnetoresistive memory elements (known as MRAM for “Magnetoresistive Random-Access Memory”), or comprising a phase-change material (known as PCM for “Phase-Change Material”).

### BACKGROUND

The main block of a memory, or memory device, is generally formed by an array of memory cells, or “bitcells”. Each memory cell may include a selection switch, for example at least one selection transistor, for selecting and electrically accessing the memory cell, and at least one memory element, or memory point, in which information, for example a bit, is stored for the memory cell.

In an RRAM memory cell, each memory element may comprise a portion of oxide or of metal electrolyte disposed between two electrodes. The document P. Polakowski et al., “Ferroelectric deep trench capacitors based on Al:HfO2 for 3D nonvolatile memory applications,” 2014 IEEE 6th International Memory Workshop (IMW), Taipei, Taiwan, 2014, pp. 1-4, describes such a configuration of an OxRAM memory cell.

A memory cell can be programmed by using a single selection transistor coupled to one of the two electrodes of the memory element or of each memory element of the memory cell. Such a memory cell is referred to as 1TnR, where n corresponds to the number of memory elements in the cell.

The memory cells are addressed by word lines, bit lines and source lines. The word lines are coupled to the memory cells in a perpendicular fashion to the bit lines so that the desired memory cells can be selected and addressed by using the word lines and the bit lines.

The dimensions of a memory element are very small compared to those of a transistor. The storage density that can be achieved by such an array of memory cells is therefore limited by the dimensions of the transistors. It is possible to improve the storage density that can be achieved by providing, in each memory cell, several separate memory elements. However, as the number of memory elements per memory cell increases, various design constraints arise, such as those related to the floating nature of the nodes (connection between the memory elements and the selection transistor in each memory cell) other than the one selected during a write operation, to the reduced number of memory cells accessible in parallel or to stray currents that are proportional to the number of parallel accesses to memory cells.

Different architectures of arrays of memory cells, called “crossbars,” have been provided. In these crossbar architectures, the selection of one of the memory cells is not performed by a transistor and the achievable storage density is greater. On the other hand, the selection of the memory cells for the implementation of the various read, write and erase operations is problematic because it involves complex nonlinear components.

### SUMMARY

There is therefore a need to provide a memory device comprising an array of memory cells capable of achieving a high storage density without the disadvantages of known architectures and without a so-called “crossbar” architecture.

An embodiment provides a solution to all or some of the disadvantages of the known solutions and provides a memory device comprising an array of memory cells, each memory cell comprising M memory elements, where M is an integer greater than or equal to 1, and a switch configured to pass or block a current between two conduction electrodes of the switch, the memory cells being addressed by word lines, source lines and bit lines, wherein:
a first of the conduction electrodes of each switch is coupled to a first electrode of each of the memory elements of a single one of the memory cells;
each word line is coupled to a control electrode of each switch of a single and same column of memory cells;
each source line is coupled to a second of the conduction electrodes of each switch of a single and same row of memory cells; and
each bit line is coupled to a second electrode of one of the memory elements of each memory cell of a single and same column of memory cells.

According to a particular embodiment, the bit lines are arranged substantially parallel to the word lines.

According to a particular embodiment, each of the memory elements comprises a resistive portion and said memory element is of the OxRAM type or comprises a solid electrolyte and said memory element is of the CBRAM type or comprises a magnetoresistive stack and said memory element is of the MRAM type or comprises a phase change material and said memory element is of the PCM type.

According to a particular embodiment, the switch of each memory cell comprises at least one MOS transistor and the control electrode of the switch corresponds to the gate of the MOS transistor and the conduction electrodes of the switch correspond to the source and drain electrodes of the MOS transistor.

According to a particular embodiment, M bit lines are associated with each of the columns of memory cells, the bit lines being different from one column to another.

According to a particular embodiment, M is between 1 and 16.

According to a particular embodiment, the memory device further comprises a control circuit configured to apply voltages to each of the bit lines, the word lines and the source lines.

According to a particular embodiment, the control circuit is configured to apply, during a write operation in at least one memory element of at least one of the memory cells of one of the columns of memory cells:
a voltage V_{SET_SBL} on the bit line coupled to said memory element;
a voltage V_{SET_SSL} on the source line coupled to the switch of said memory cell;
a voltage V_{SET_UBL} on the bit lines other than the one coupled to said memory element;
a voltage V_{SET_USL} on the source lines other than the one coupled to the switch of said memory cell;
where V_{SET_SBL}>V_{SET_USL}>V_{SET_UBL}≥V_{SET_SSL}.

According to a particular embodiment, in a first configuration:
the voltage V_{SET_SBL} is equal to (3−α)·V_{L};
the voltage V_{SET_SSL} is equal to 0;
the voltage V_{SET_UBL} is equal to V_{L};
the voltage V_{SET_USL} is equal to approximately 2·V_{L};
or, in a second configuration:
the voltage V_{SET_SBL} is equal to approximately (2−α)·V_{L};
the voltage V_{SET_SSL} is equal to 0;
the voltage V_{SET_UBL} is equal to approximately 0;
the voltage V_{SET_USL} is equal to approximately V_{L};
where V_{L} corresponds to a value of a non-write limit voltage in said memory element, and α corresponds to an uncertainty factor due to the finite conductance of the switch of said memory cell and to the uncertainty of the conductance state of the M memory elements of said memory cell.

According to a particular embodiment, during the write operation, the control circuit is configured to apply, to the word line coupled to the switch of said memory cell, a voltage for turning on the switch of said memory cell, and to the word lines other than the one coupled to the switch of said memory cell, a blocking voltage for blocking the switches coupled to these word lines.

According to a particular embodiment, the control circuit is configured to apply, during an erase operation in at least one memory element of at least one of the memory cells:
a voltage V_{RESET_SBL} on the bit line coupled to said memory element;
a voltage V_{RESET_SSL} on the source line coupled to the switch of said memory cell;
a voltage V_{RESET_UBL} on the bit lines other than the one coupled to said memory element;
a voltage V_{RESET_USL} on the source lines other than the one coupled to the switch of said memory cell;
where V_{RESET_SSL}>V_{RESET_UBL}≥V_{RESET_USL}>V_{RESET_SBL}.

According to a particular embodiment, in a first configuration:
the voltage V_{RESET_SBL} is equal to 0;
the voltage V_{RESET_SSL} is equal to (3−α)·V_{L};
the voltage V_{RESET_UBL} is equal to (2−α)·V_{L};
the voltage V_{RESET_USL} is equal to (1−α)·V_{L};
or, in a second configuration:
the voltage V_{RESET_SBL} is equal to 0;
the voltage V_{RESET_SSL} is equal to 2·V_{L};
the voltage V_{RESET_UBL} is equal to V_{L};
the voltage V_{RESET_USL} is equal to approximately V_{L}.

According to a particular embodiment, during the erase operation, the control circuit is configured to apply, to the word line coupled to the switch of said memory cell, a voltage that turns on the switch of said memory cell, and to the word lines other than the one coupled to the switch of said memory cell, a blocking voltage for blocking the switches coupled to these word lines.

According to a particular embodiment, the control circuit is configured to successively apply, during a read operation of several memory elements of each memory cell of one of the columns of the array, a non-zero voltage V_{R} to each of the bit lines coupled to said memory elements, a zero voltage being applied to the bit line(s) coupled to the other memory elements;
and the memory device further comprises a circuit for reading currents flowing in the source lines, configured to read these currents each time the voltage V_{R} is applied to the bit lines coupled to said memory elements.

According to a particular embodiment, the control circuit is configured to apply, during a read operation of a memory element of each memory cell of one of the columns of the array, a non-zero voltage V_{R} to the bit line coupled to said memory element, a zero voltage being applied to the bit line(s) coupled to the other memory elements;
and the memory device further comprises a circuit for reading currents flowing in the source lines.

According to a particular embodiment, the memory device further comprises a calculation circuit configured for determining information stored in each of the memory elements being read from a conductance value of one of the switches, the value of the voltage V_{R} and the values of the currents flowing in the source lines.

### BRIEF DESCRIPTION OF THE DRAWINGS

The foregoing features and advantages, as well as others, will be described in detail in the following description of examples and particular embodiments given by way of illustration and not limitation with reference to the accompanying drawings, in which:

FIG. 1 illustrates an electrical diagram of a part of an array of memory cells of a memory device according to a particular embodiment;

FIG. 2 schematically illustrates an example of a configuration during a write operation in memory cells of a memory device according to a particular embodiment;

FIG. 3 schematically illustrates an example of a configuration during an erase operation in memory cells of a memory device according to a particular embodiment; and

FIG. 4 schematically illustrates an example of a configuration during a read operation of memory cells of a memory device according to a particular embodiment.

### DETAILED DESCRIPTION OF THE PRESENT EMBODIMENTS

Like features have been designated by like references in the various figures. In particular, the structural and/or functional features that are common among the various embodiments may have the same references and may dispose identical structural, dimensional and material properties.

For the sake of clarity, only the steps and elements that are useful for an understanding of the embodiments described herein have been illustrated and described in detail. In particular, various elements (read circuit, row decoder, column decoder, control circuit, etc.) of the memory device are not detailed. A detailed embodiment of these elements is within the capability of a person skilled in the art using the functional description given below.

In the various figures, the visible elements are not shown to the same scale in relation to each other in order to facilitate understanding of these figures.

Unless indicated otherwise, when reference is made to two elements connected together, this signifies a direct connection without any intermediate elements other than conductors, and when reference is made to two elements coupled together, this signifies that these two elements can be connected or they can be coupled via one or more other elements. In addition, the term “coupled” is used to refer to an electrical coupling between elements.

In the following disclosure, unless indicated otherwise, when reference is made to absolute positional qualifiers, such as the terms “front”, “back”, “top”, “bottom”, “left”, “right”, etc., or to relative positional qualifiers, such as the terms “above”, “below”, “higher”, “lower”, etc., or to qualifiers of orientation, such as “horizontal”, “vertical”, etc., reference is made, unless otherwise specified, to the orientation of the figures in a normal position of use of the device. However, these terms do not presume the actual position and the actual orientation of the device during use.

Throughout the document, the terms “row” and “column” are used with reference to the configurations shown in the figures, with a row referring to a horizontal orientation and a column referring to a vertical orientation. Alternatively, these terms may be interchanged depending on the actual orientation of the memory device, in this case with rows corresponding to columns and columns corresponding to rows.

Unless specified otherwise, the expressions “about”, “approximately”, “substantially” and “in the order of” signify within 10%, and preferably within 5%.

An electrical diagram of an example of a memory device 100 according to a particular embodiment is described below in connection with FIG. 1.

The memory device 100 comprises several memory cells arranged side by side, for example in the same plane, in the form of an array. FIG. 1 shows four memory cells 102.1, 102.2, 102.3 and 102.4. The memory cells 102.1 and 102.2 are part of the same row of the array and the memory cells 102.3 and 102.4 are part of the same row of the array, different from the one comprising the memory cells 102.1 and 102.2. The memory cells 102.1 and 102.3 are part of the same column of the array and the memory cells 102.2 and 102.4 are part of the same column of the array, different from the one comprising the memory cells 102.1 and 102.3. The total number of rows and columns in the array depends in particular on the desired storage capacity for the memory device 100.

The memory cells of the device 100 are of the 1T-MR type, with M an integer greater than or equal to 1, and by example between 2 and 16 or advantageously between 2 and 8.

Each memory cell of the device 100 comprises a switch 104, or selector, corresponding, for example, to an N-type or P-type MOS selection transistor, or a transmission gate formed from an NMOS transistor and a PMOS transistor. Alternatively, other types of switches 104 for selecting one or more memory cells during a write (or set), erase (or reset) or read operation are possible. Each switch 104 is configured to open or close a conduction path formed between first and second conduction electrodes of the switch 104 (corresponding to the source and drain electrodes when the switch 104 corresponds to a MOS transistor, the conduction path being formed from the drain electrode to the source electrode in the case of an NMOS transistor, or formed from the source electrode to the drain electrode in the case of a PMOS transistor), i.e. to allow or prevent the passage of a current between its conduction electrodes. This passage or non-passage of the current is controlled by applying a sufficient voltage to a control electrode of the switch 104 (corresponding to the gate when the switch 104 corresponds to a MOS transistor). When the switch 104 corresponds to an NMOS transistor, the voltage applied to its gate is high enough to turn on the NMOS transistor, and when the switch 104 corresponds to a PMOS transistor, the voltage applied to its gate is low enough to turn on the PMOS transistor. When the switch 104 corresponds to a transmission gate, the control voltages applied to its control inputs must be sufficiently different from each other and such that the transmission gate is turned on.

Each memory cell of the device 100 comprises M memory elements 106, for example resistive elements of the RRAM type, in which information is to be stored. For example, each memory element 106 may be of the OxRAM type and comprises a resistive portion comprising HfO₂ or any other oxide suitable for storing information by means of the formation of a conductive filament or conductive filaments therein. This resistive portion may be disposed between two electrodes, each comprising, for example, a first part of Ti, TiN, or TaN and being disposed against the resistive portion, and at least a second part comprising, for example, tungsten, TiN, copper or cobalt and serving for the electrical interconnection of the memory element 106. According to one embodiment, the memory element 106 may optionally include a portion of getter material based on titanium, tantalum, hafnium, or any other material having an electrochemical affinity with oxygen when the memory element 106 is of the OxRAM type. Such a portion of getter material may contribute to the creation of one or more electrically conductive filaments in the resistive portion.

Alternatively, each memory element 106 may be of another type, for example CBRAM, by replacing the constituent parts of these OxRAM memory elements with their equivalents in CBRAM memory elements, namely the lower and upper electrodes with a chemically inert electrode and a chemically active electrode, respectively, and the resistive layer with a solid electrolyte. According to another example, each memory element 106 may be of the MRAM type, by replacing the resistive layer with a magnetoresistive stack comprising a tunnel oxide layer, for example based on MgO, disposed between two magnetic layers, for example based on cobalt. According to another example, each memory element 106 may be of the PCM type, by replacing the resistive layer with a layer of phase-change material.

In the example shown in FIG. 1, each memory cell 102.1-102.4 comprises several memory elements 106, four of these memory elements 106 being shown for each of the memory cells.

In each memory cell of the device 100, a first electrode of each memory element 106 is coupled to a first conduction electrode of the switch 104 of the cell. For example, when the switch 104 corresponds to a MOS transistor, the first conduction electrode of the switch 104 corresponds to the source or drain electrode of the transistor (e.g., the drain electrode in the case of an NMOS transistor). In each memory cell, the first electrode of each memory element 106 of the memory cell and the first conduction electrode of the switch 104 of the memory cell are coupled to a central node 107 of the memory cell. The central nodes 107 of the memory cells are not electrically connected to each other, either by row or by column. In other words, a first of the conduction electrodes of each switch 104 is coupled to a first electrode of each of the memory elements 106 of only one of the memory cells.

The memory cells of the device 100 are addressed by word lines 108, bit lines 110 and source lines 112. Each of the word lines 108 is coupled to the control electrode of the switches 104 (the gate in the case of switches 104 corresponding to MOSFET transistors) belonging to a single and same column of memory cells. When the switches 104 correspond to transmission gates, two word lines 108 are associated with each column of memory cells, on which complementary control signals are sent and are to be received on the control inputs of the transmission gates. In addition, each of the source lines 112 is coupled to the second conduction electrode of the switches 104 (for example the source in the case of switches 104 corresponding to NMOS transistors) forming part of a single and same line/row of memory cells. Finally, each of the bit lines 110 is coupled to a second electrode of the memory element 106 or of a single one of the memory elements 106 of each memory cell of a single and same column of memory cells.

The number of bit lines 110 associated with each of the memory cell columns depends on the number of memory elements 106 present in each memory cell. For example, when each memory cell has a single memory element 106, a single bit line 110 can be associated with each of the memory cell columns and coupled to a second electrode of the memory element 106 of each of the memory cells in that column. More generally, when each memory cell has M memory elements 106, M bit lines 110 can be associated with each of the memory cell columns, and each of them can be coupled to a second electrode of one of the M memory elements 106 of each of the memory cells in that column. In the example shown in FIG. 1, four memory elements 106 are shown for each of the memory cells 102.1-102.4, and four bit lines 110 are shown for each of the memory cell columns, such that each of these bit lines 110 is coupled to the second electrode of one of the memory elements 106 of each memory cell and separate from those to which the other bit lines 110 associated with this column of memory cells are coupled.

The device 100 also includes a control circuit (not shown in the figures) for the voltages applied to each of the bit lines 110, the word lines 108 and the source lines 112. This circuit is capable of applying the appropriate voltages to these lines for the implementation of set, reset and read operations in the memory elements 106 of the memory cells.

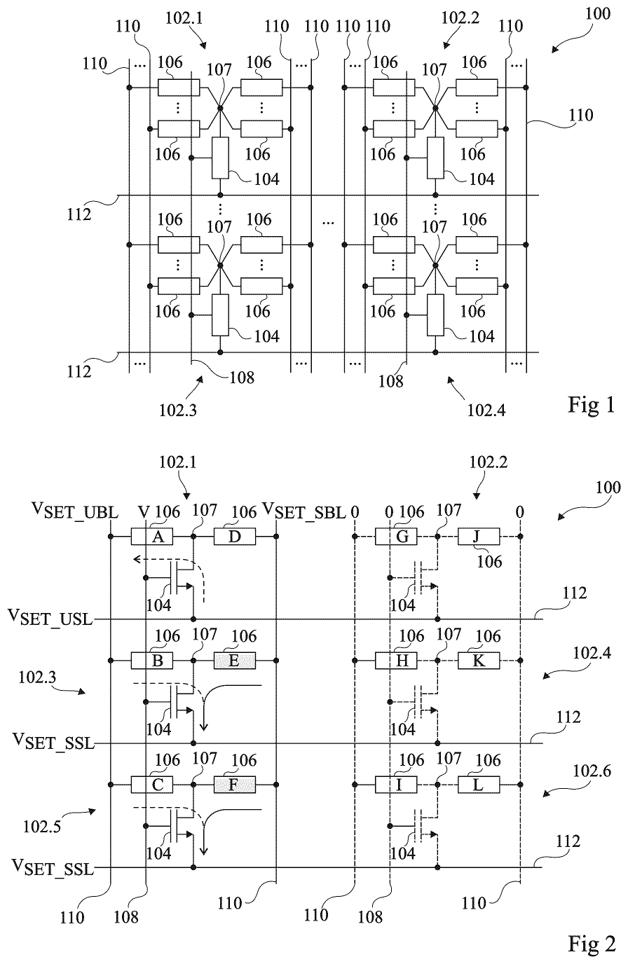

FIG. 2 schematically illustrates an example of the configuration of the device 100 during a write operation in the memory cells of the memory device 100. In this example, each of the memory cells, referenced 102.1 to 102.6 in FIG. 2, comprises two memory elements 106 designated by the letters “A” to “L”. The memory cells 102.1 and 102.2 are part of a first row of the array, the memory cells 102.3 and 102.4 are part of a second row of the array and the memory cells 102.5 and 102.6 are part of a third row of the array. Furthermore, the memory cells 102.1, 102.3 and 102.5 are part of a first column of the array, and the memory cells 102.2, 102.4 and 102.6 are part of a second column of the array.

In the example shown in FIG. 2, the switches 104 correspond to NMOS transistors whose gates are coupled to the word lines 108, whose sources are coupled to the source lines 112 and whose drains are coupled to the memory elements 106, forming the central connection nodes 107 of the memory cells.

In the example shown in FIG. 2, a write operation is to be performed in only one of the memory elements 106 of each of the two memory cells 102.3 and 102.5 belonging to the same column and to two different rows of the array, these memory elements 106 being those designated by the letters “E” and “F”.

To perform a write operation, a voltage V_{SET_SBL} may be applied to the bit line(s) 110 coupled to the memory element 106 or to the memory elements 106 in which the write operation is to be performed. In the example shown in FIG. 2, the voltage V_{SET_SBL} is applied to the bit line 110 coupled to the memory elements 106 designated by the letters “D”, “E” and “F”. In addition, a voltage V_{SET_UBL} may be applied to any other bit line(s) 110 coupled to the other memory elements 106 in this same column but in which the write operation is not to be performed. In the example shown in FIG. 2, the voltage V_{SET_UBL} is applied to the bit line 110 coupled to the memory elements 106 designated by the letters “A”, “B” and “C”. Finally, the same voltage, for example of zero, may be applied to the bit lines 110 associated with each of the columns not involved in the write operation. In the example shown in FIG. 2, a zero voltage is applied to the bit lines 110 coupled to the memory elements 106 designated by the letters “G”, “H”, “I”, “J”, “K” and “L”.

In addition, for this write operation, a voltage capable of turning on a switch 104 can be applied to the word line 108 coupled to the switches 104 of the column to which the memory cell(s) in which the write operation is to be performed belong(s). In the example shown in FIG. 2, such a voltage V is applied to the word line 108 coupled to the switches 104 of the first column to which the memory cells 102.1, 102.3 and 102.5 belong. A blocking voltage of the switches 104 may be applied to the other word lines 108 coupled to the switches 104 of the memory cells in the columns not involved in the write operation. In the example shown in FIG. 2, a zero voltage is applied to the word line 108 coupled to the memory cells 102.2, 102.4 and 102.6 of the second column.

Finally, for this write operation, a voltage V_{SET_SSL} may be applied to the source line(s) 112 coupled to the switch(es) 104 of the memory cell(s) in which the write operation is to be performed. In the example shown in FIG. 2, the voltage V_{SET_SSL} is applied to the source lines 112 coupled to the switches 104 of the lines/rows to which the memory cells 102.3, 102.4, 102.5 and 102.6 belong. In addition, a voltage V_{SET_USL} may be applied to the source lines 112 coupled to the switches 104 of the memory cells 102 of the rows not involved in the write operation. In the example shown in FIG. 2, the voltage V_{SET_USL} is applied to the source line 112 coupled to the switches 104 of the memory cells 102.1 and 102.2 of the first row.

To perform the desired write operation, the voltages V_{SET_SBL}, V_{SET_SSL}, V_{SET_UBL} and V_{SET_USL} may be such that V_{SET_SBL}>V_{SET_USL}>V_{SET_UBL}≥V_{SET_SSL}. The values of these voltages can be chosen so that a sufficiently high voltage is applied to the memory element(s) 106 in which the write operation is to be performed, while limiting the absolute voltage seen by the other memory elements 106, which is less than a value V_{L} corresponding to a value of a non-write limit voltage in a memory element 106, i.e. the value below which a write operation does not occur with a certainty sufficient to ensure the operation of the memory.

In a first configuration that maximizes the write voltage seen by the memory element(s) 106 in which the write operation is to be performed, the values of the voltages applied to the word lines 108 and the bit lines 110 belonging to the column(s) containing the memory elements to be written and to the source lines 112 may, as a first approximation, be such that:
the voltage V_{SET_SBL} is equal to (3−α)·V_{L};
the voltage V_{SET_SSL} is equal to 0;
the voltage V_{SET_UBL} is equal to V_{L};
the voltage V_{SET_USL} is equal to approximately 2·V_{L}.

α corresponds to an uncertainty factor due to the uncertainty in the voltage of the nodes 107 caused by the finite conductance of the switch 104 and the conductance state, which is a priori unknown, of the memory elements 106 connected to this node 107.

The values of the above voltages and of the factor α may vary and can be determined by implementing a simulation.

For example, considering switches 104 formed by NMOS transistors in 22 nm technology, with a supply voltage of 1.8 V for the array of memory cells, these voltages may be, for example:

$${V}_{SET \_ SBL} = 1.7 V ; {V}_{SET \_ SSL} = 0 V ; {V}_{SET \_ UBL} = 0.7 V ; {V}_{SET \_ USL} = 1.35 V .$$

In a second configuration that minimizes the stray currents in the memory element(s) 106 in which the write operation is not to be performed and which belong(s) to a memory cell 102 comprising a memory element to be written, in order to more accurately measure the write current that is used, the values of the voltages applied to the word lines 108 and to the bit lines 110 belonging to the column(s) containing the memory elements to be written and to the source lines 112 may be such that:
the voltage V_{SET_SBL} is equal to (2−α)·V_{L};
the voltage V_{SET_SSL} is equal to 0;
the voltage V_{SET_UBL} is equal to approximately 0;
the voltage V_{SET_USL} is equal to approximately V_{L}.

For example, considering switches 104 formed by NMOS transistors in 22 nm technology, with a supply voltage of 1.8 V for the array of memory cells, these voltages may be, for example:

$${V}_{SET \_ SBL} = 1.1 V ; {V}_{SET \_ SSL} = 0 V ; {V}_{SET \_ UBL} = 0 V ; {V}_{SET \_ USL} = 0.7 V .$$

In FIG. 2, which illustrates the implementation of a write operation in the memory elements 106 designated by the letters “E” and “F”, the solid arrows correspond to the write currents flowing between the bit line 110 coupled to the memory elements “E” and “F” and the source lines 112 coupled to the memory cells 102.3 and 102.5, passing through the memory elements “E” and “F” and thus writing the memory state of these elements to a high state. The dotted arrows correspond to the stray currents flowing in certain switches 104 and certain memory elements 106 that are not to change memory state. These stray currents are due in particular to the various voltages applied to the bit lines 110 associated with the column of memory cells 102 to which the memory elements 106 in which the write operation is to be performed belong.

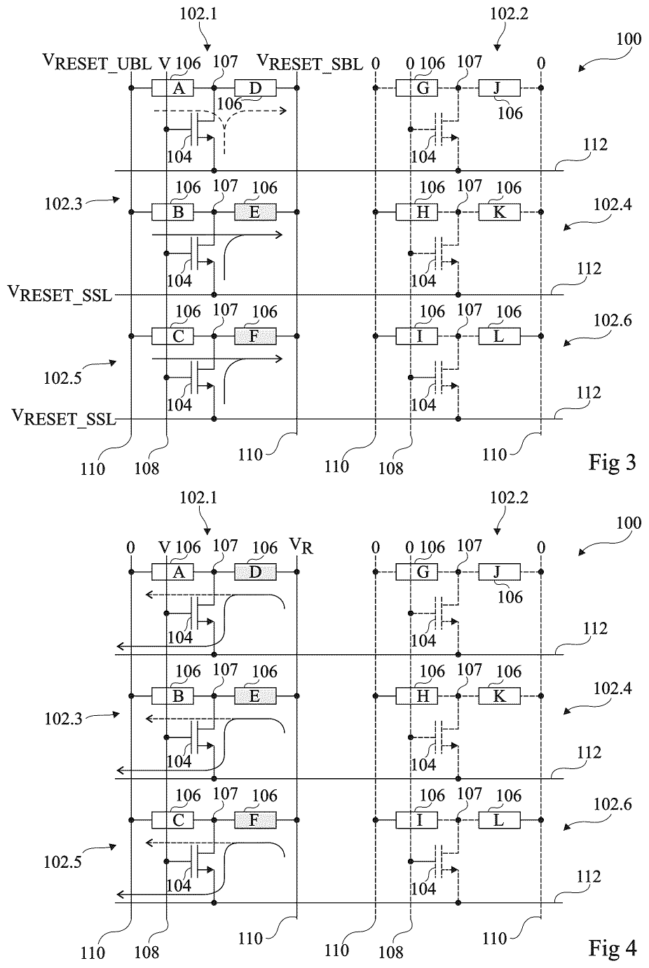

FIG. 3 schematically illustrates an example of a configuration of the device 100 during an erase operation in memory cells of the memory device 100. As in the example in FIG. 2, only two memory elements 106 are shown for each of the memory cells referenced 102.1 to 102.6, and the switches 104 correspond to NMOS transistors.

In the example shown in FIG. 3, the erase operation is to be performed in only one of the memory elements 106 of each of two memory cells 102.3 and 102.5 belonging to the same column and to two different rows of the array, these memory elements 106 being those designated by the letters “E” and “F”.

To perform this erase operation, a voltage V_{RESET_SBL} can be applied to the bit line(s) 110 coupled to the memory element 106 or to the memory elements 106 in which the erase operation is to be performed. In the example shown in FIG. 3, the voltage V_{RESET_SBL} is applied to the bit line 110 coupled to the memory elements 106 designated by the letters “D”, “E” and “F”. In addition, a voltage V_{RESET_UBL} may be applied to any other bit line(s) 110 coupled to the other memory elements 106 of the memory cells 102 in which the erase operation is to be performed. In the example shown in FIG. 3, the voltage V_{RESET_UBL} is applied to the bit line 110 coupled to the memory elements 106 designated by the letters “A”, “B” and “C”. Finally, the same voltage, for example of zero, can be applied to the bit lines coupled to the memory elements 106 of the memory cells 102 of each of the columns not involved in the erase operation. In the example shown in FIG. 3, a zero voltage is applied to the bit lines 110 coupled to the memory elements 106 designated by the letters “G”, “H”, “I”, “J”, “K” and “L”.

In addition, for this erase operation, a voltage capable of turning on a switch 104 can be applied to the word line 108 coupled to the switches 104 of the column to which the memory cell(s) 102 in which the erase operation is to be performed belong(s). In the example shown in FIG. 3, such a voltage V is applied to the word line 108 coupled to the switches 104 of the first column to which the memory cells 102.1, 102.3 and 102.5 belong. A blocking voltage for the switches 104 may be applied to the other word lines 108 coupled to the switches 104 of the memory cells 102 of the columns not involved in the erase operation. In the example shown in FIG. 3, a zero voltage is applied to the word line 108 coupled to the memory cells 102.2, 102.4 and 102.6 of the second column.

Finally, for this erase operation, a voltage V_{RESET_SSL} can be applied to the source line(s) 112 coupled to the switch(es) 104 of the memory cell(s) in which the erase operation is to be performed. In the example shown in FIG. 3, the voltage V_{RESET_SSL} is applied to the source lines 112 coupled to the switches 104 of the lines/rows to which the memory cells 102.3, 102.4, 102.5 and 102.6 belong. In addition, a voltage V_{RESET_USL} can be applied to the source lines 112 coupled to the switches 104 of the memory cells 102 of the lines/rows not involved in the erase operation. In the example shown in FIG. 3, the voltage V_{RESET_USL} is applied to the source line 112 coupled to the switches 104 of the memory cells 102.1 and 102.2 of the first line/row.

In FIG. 3, the solid arrows correspond to the erase currents flowing between the source lines 112 coupled to the memory cells 102.3 and 102.5 and the bit line 110 coupled to the memory elements “E” and “F”, passing through the memory elements “E” and “F” in the opposite direction to the one of the write currents described above and thus changing the memory state of these elements, switching them to a low state. The dotted arrows correspond to the stray currents flowing in particular in the switch 104 and the memory elements 106 of the memory cell 102.1 that is not involved in the erase operation. These stray currents are due in particular to the various voltages applied to the bit lines 110 associated with the column of memory cells 102 to which the memory elements 106 belong, in which the erase operation is to be performed. Furthermore, in the example described, the stray currents flowing through the memory elements B and C also contribute to the erase operation of the cells E and F.

To perform the desired erase operation, the voltages V_{RESET_SBL}, V_{RESET_SSL}, V_{RESET_UBL} and V_{RESET_USL} may be such that V_{RESET_SSL}>V_{RESET_UBL}≥V_{RESET_USL}>V_{RESET_SBL}. The values of these voltages can be chosen so that a sufficiently high voltage is applied to the memory element(s) 106 in which the erase operation is to be performed, while limiting the absolute voltage seen by the other memory elements 106, which is less than a value V_{L} corresponding to a value of a non-write limit voltage in a memory element 106, i.e. the value below which a write or erase operation does not occur with a certainty sufficient to ensure the operation of the memory.

In a first configuration allowing the erase voltage seen by the memory element(s) 106 in which the erase operation is to be performed to be maximized, the values of the voltages applied to the word lines 108 and to the bit lines 110 belonging to the column(s) containing the memory elements to be erased and to the source lines 112 may be such that:
the voltage V_{RESET_SBL} is equal to 0;
the voltage V_{RESET_SSL} is equal to (3−α)·V_{L};
the voltage V_{RESET_UBL} is equal to (2−α)·V_{L};
the voltage V_{RESET_USL} is equal to approximately (1−α)·V_{L}.

α corresponds to an uncertainty factor due to the uncertainty in the voltage of the nodes 107 caused by the finite conductance of the switch 104 and the conductance state, which is a priori unknown, of the memory elements 106 connected to this node 107.

For example, considering switches 104 formed by NMOS transistors in 22 nm technology, with a supply voltage equal to 1.8 V for the array of memory cells, these voltages may be, for example: V_{RESET_SBL}=0 V; V_{RESET_SSL}=1.8 V; V_{RESET_UBL}=1.2 V; V_{RESET_USL}=0.5 V.

In a second configuration that minimizes the leakage currents in the memory element(s) 106 not involved in the erase operation, the bit lines 110 and the source lines 112 may be such that:
the voltage V_{RESET_SBL} is equal to 0;
the voltage V_{RESET_SSL} is equal to 2·V_{L};
the voltage V_{RESET_UBL} is equal to V_{L};
the voltage V_{RESET_USL} is equal approximately to V_{L}.

For example, considering switches 104 formed by NMOS transistors in 22 nm technology, with a supply voltage of 1.8 V for the array of memory cells, these voltages may be, for example:

$${V}_{RESET \_ SBL} = 0 V ; {V}_{RESET \_ SSL} = 1.4 V ;$$

$${V}_{RESET \_ UBL} = 0.7 V ; {V}_{RESET \_ USL} = 0.7 V .$$

FIG. 4 schematically shows an example of a configuration of the device 100 during a read operation of memory cells of the memory device 100. As in the example shown in FIGS. 2 and 3, only two memory elements 106 are shown for each of the memory cells referenced 102.1 to 102.6, and the switches 104 correspond to NMOS transistors.

In the example shown in FIG. 4, the read operation is to be performed in only one of the memory elements 106 of each of the memory cells 102.1, 102.3 and 102.5 belonging to the same column of the array, these memory elements 106 being those designated by the letters “D”, “E” and “F” in FIG. 4.

To perform this read operation, a non-zero voltage V_{R} is applied to the bit line 110 coupled to the memory elements 106 to be read and a zero voltage is applied to the bit line(s) coupled to the other memory elements 106. The value of the voltage V_{R} is chosen to be sufficiently low so as not to trigger a write operation in the memory elements 106. For example, the value of the voltage V_{R} may be equal to 0.2 V.

In addition, to perform this read operation, a voltage capable of turning on a switch 104 is applied to the word line 108 coupled to the switches 104 of the column to which the memory cell(s) 102 for which the read operation is to be performed belong(s). In the example shown in FIG. 4, such a voltage V is applied to the word line 108 coupled to the switches 104 of the first column to which the memory cells 102.1, 102.3 and 102.5 belong. A blocking voltage for the switches 104, for example of zero, is applied to the other word lines 108 coupled to the switches 104 of the memory cells 102 of the columns not involved in the erase operation. In the example shown in FIG. 4, a zero voltage is applied to the word line 108 coupled to the memory cells 102.2, 102.4 and 102.6 of the second column.

Finally, for this read operation, a zero voltage is applied to the source lines 112, and the current flowing through the source lines 112 is measured.

In FIG. 4, the solid arrows correspond to the read currents flowing between the bit line 110 coupled to the memory elements 106 being read and each of the source lines 112. The current levels obtained on the various source lines 112 are representative of the information stored in the memory elements 106 being read. To read these currents, the memory device 100 may include a read circuit, not shown in FIG. 4. In addition, the dotted arrows correspond to the leakage currents flowing through the other memory elements 106 in the column (the memory elements “A”, “B” and “C” in FIG. 4).

Thus, the read operations performed in the various memory cells of the column being read can be performed in parallel with each other.

A first way to perform this read operation may consist of implementing, for all the memory cells in the same column of the array, a grouped read operation of several memory elements 106 of each of the memory cells. Knowing the value of the conductance γ_{T} of each of the switches 104 (this conductance γ_{T} being considered as identical for all the switches 104), and based on the currents Iᵢ measured in the source lines 112 by successively applying the voltage V_{R} to each of the bit lines coupled to the memory elements to be read (and by leaving a zero voltage on the other bit lines), it is possible to calculate the memory states of the memory elements 106 by calculating the conductances

$${γ}_{i} = \frac{{γ}_{T} {X}_{i}}{{γ}_{T} - {\sum }_{j} {X}_{j}}$$

of each memory element 106 with

$${X}_{i} = \frac{{I}_{i}}{{V}_{R}} ,$$

where i and j are between 1 and M, the number of memory elements 106 per memory cell 102. Such a read operation makes it possible to precisely determine, in a grouped manner, the conductance of all the M memory elements 106 of each memory cell in the same column of the array.

A second way to perform this read operation may consist of implementing, for all the memory cells in the same column of the array, an approximate individual read operation of a memory element 106 of each of the memory cells. Knowing the value of the conductance γ_{T} of each of the switches 104 (this conductance γ_{T} being considered as identical for all the switches 104), and based on the currents I_{T} measured in the source lines 112 by applying the voltage V_{R} to the bit line coupled to the memory elements to be read (and by leaving a zero voltage on the other bit lines), it is possible to calculate the memory states of the memory elements 106 by calculating the conductances

$${γ}_{i} = \frac{{I}_{T}}{{V}_{R}}$$

of each memory element 106. This read operation is all the more accurate as the sum of the conductances of the memory elements 106 of a memory cell is small compared to the conductance γ_{T} Such a read operation makes it possible to read approximately one memory element 106 of each memory cell in the same column simultaneously.

The voltage values given in the above examples may differ from those indicated. Other voltage levels may be used, for example to adjust the obtained levels of stray currents. In addition, the finite conductance of the transistor and the uncertainty about the resistive state of the devices may be considered to optimize the values of the applied voltages. Furthermore, it is possible to exploit the obtained stray conductance, for example to avoid the saturation of the current in the transistor (non-linear effect) and to avoid a collapse of the conductance, whether dynamic or global, when a high current passes through the transistor. Finally, in the read operation example described above, the read currents are obtained on the source lines 112. Other read operation variants are possible.

In these various operations, a column of memory cells 102 is active.

In the various embodiments, examples and variants, the word lines 108 are parallel, or substantially parallel, to the bit lines 110. Such addressing of the memory cells 102 has several advantages.

Indeed, thanks to the architecture of the array of memory cells 102 of the device 100, all the central nodes 107 formed, in each memory cell 102 belonging to the active column, at the point of connection of the first conduction electrode of the switch 104 with the first electrode of each of the M memory elements 106 of the memory cell are controllable by means of the electrical potentials applied to the source lines 112.

Furthermore, by considering a memory cell array comprising N lines/rows of memory cells 102, and therefore N source lines 112, N memory cells are therefore accessible simultaneously in parallel for write, erase and read operations.

Furthermore, the values of the stray currents flowing in the memory cells 102 during write, erase or read operations are independent of the number of memory cells involved in these operations.

Furthermore, by considering an array of memory cells 102 each comprising M memory elements 106 coupled to a switch 104, it may be advantageous to minimize the value of M while ensuring a conductance and a saturation current of the switch 104 sufficient for writing to the memory elements 106, and a desired storage density. This is because the larger M is, the greater the leakage currents can be, which can reduce the energy efficiency of the cell and constrain the peripheral electronics of the array. The value of M can therefore be chosen by ensuring that the performed write operations do not disturb the other memory elements 106 coupled to the switch 104. In addition, a large value of M can reduce the area lost between the switches 104.

Finally, minimizing the number of rows in the array of the memory cells 102 relative to its number of columns can minimize the stray currents while maintaining a good control of the central nodes 107 and the same size of memory points.

Various examples of embodiments and variants have been described. Those skilled in the art will understand that certain features of these various examples of embodiments and variants may be combined, and other variants will be apparent to those skilled in the art.

Finally, the practical implementation of the examples of embodiments and variants described is within the reach of those skilled in the art based on the functional indications given above.

1. A memory device comprising an array of memory cells, each memory cell comprising M memory elements, where M is an integer greater than or equal to 1, and a switch configured to pass or block a current between two conduction electrodes of the switch, the memory cells being addressed by word lines, source lines and bit lines, wherein:
a first of the conduction electrodes of each switch is coupled to a first electrode of each of the memory elements of a single one of the memory cells;
each word line is coupled to a control electrode of each switch of a single and same column of memory cells;
each source line is coupled to a second of the conduction electrodes of each switch of a single and same row of memory cells;
each bit line is coupled to a second electrode of one of the memory elements of each memory cell of a single and same column of memory cells.

2. The memory device according to claim 1, wherein each of the memory elements comprises a resistive portion and said memory element is of the OxRAM type, or comprises a solid electrolyte and said memory element is of the CBRAM type, or comprises a magnetoresistive stack and said memory element is of the MRAM type, or comprises a phase change material and said memory element is of the PCM type.

3. The memory device according to claim 1, wherein the switch of each memory cell comprises at least one MOS transistor and wherein the control electrode of the switch corresponds to the gate of the MOS transistor and the conduction electrodes of the switch correspond to the source and drain electrodes of the MOS transistor.

4. The memory device according to claim 1, wherein M bit lines are associated with each of the columns of memory cells, the bit lines being different from one column to another.

5. The memory device according to claim 1, wherein M is between 1 and 16.

6. The memory device according to claim 1, further comprising a control circuit configured to apply voltages to each of the bit lines, the word lines and the source lines.

7. The memory device according to claim 6, wherein the control circuit is configured to apply, during a write operation in at least one memory element of at least one of the memory cells of one of the columns of memory cells:
a voltage V_{SET_SBL} on the bit line coupled to said memory element;
a voltage V_{SET_SSL} on the source line coupled to the switch of said memory cell;
a voltage V_{SET_UBL} on the bit lines other than the one coupled to said memory element;
a voltage V_{SET_USL} on the source lines other than the one coupled to the switch of said memory cell;
where V_{SET_SBL}>V_{SET_USL}>V_{SET_UBL}≥V_{SET_SSL}.

8. The memory device according to claim 7, wherein, in a first configuration:
the voltage V_{SET_SBL} is equal to (3−α)·V_{L};
the voltage V_{SET_SSL} is equal to 0;
the voltage V_{SET_UBL} is equal to V_{L};
the voltage V_{SET_USL} is equal to approximately 2·V_{L};
or in which, in a second configuration:
the voltage V_{SET_SBL} is equal to approximately (2−α)·V_{L};
the voltage V_{SET_SSL} is equal to 0;
the voltage V_{SET_UBL} is equal to approximately 0;
the voltage V_{SET_USL} is equal to approximately V_{L};
where V_{L} corresponds to a value of a non-write limit voltage in said memory element, and α corresponds to an uncertainty factor due to the finite conductance of the switch of said memory cell and to the uncertainty of the conductance state of the M memory elements of said memory cell.

9. The memory device according to claim 7, wherein, during the write operation, the control circuit is configured to apply, to the word line coupled to the switch of said memory cell, a voltage for turning on the switch of said memory cell, and to the word lines other than the one coupled to the switch of said memory cell, a blocking voltage for blocking the switches coupled to these word lines.

10. The memory device according to claim 6, wherein the control circuit is configured to apply, during an erase operation in at least one memory element of at least one of the memory cells:
a voltage V_{RESET_SBL} on the bit line coupled to said memory element;
a voltage V_{RESET_SSL} on the source line coupled to the switch of said memory cell;
a voltage V_{RESET_UBL} on the bit lines other than the one coupled to said memory element;
a voltage V_{RESET_USL} on the source lines other than the one coupled to the switch of said memory cell;
with V_{RESET_SSL}>V_{RESET_UBL}≥V_{RESET_USL}>V_{RESET_SBL}.

11. The memory device according to claim 10, wherein, in a first configuration:
the voltage V_{RESET_SBL} is equal to 0;
the voltage V_{RESET_SSL} is equal to (3−α)·V_{L};
the voltage V_{RESET_UBL} is equal to (2−α)·V_{L};
the voltage V_{RESET_USL} is equal to (1−α)·V_{L};
or in which, in a second configuration:
the voltage V_{RESET_SBL} is equal to 0;
the voltage V_{RESET_SSL} is equal to 2·V_{L};
the voltage V_{RESET_UBL} is equal to V_{L};
the voltage V_{RESET_USL} is equal to approximately V_{L}.

12. The memory device according to claim 10, in which, during the erase operation, the control circuit is configured to apply, to the word line coupled to the switch of said memory cell, a voltage that turns on the switch of said memory cell, and to the word lines other than the one coupled to the switch of said memory cell, a blocking voltage for blocking the switches coupled to these word lines.

13. The memory device according to claim 6, wherein the control circuit is configured to successively apply, during a read operation of several memory elements of each memory cell of one of the columns of the array, a non-zero voltage V_{R} to each of the bit lines coupled to said memory elements, a zero voltage being applied to the bit line(s) coupled to the other memory elements;
and further comprising a circuit for reading currents flowing in the source lines, configured to read these currents each time the voltage V_{R} is applied to the bit lines coupled to said memory elements.

14. The memory device according to claim 6, wherein the control circuit is configured to apply, during a read operation of a memory element of each memory cell of one of the columns of the array, a non-zero voltage V_{R} to the bit line coupled to said memory element, a zero voltage being applied to the bit line(s) coupled to the other memory elements;
and further comprising a circuit for reading currents flowing in the source lines.

15. The memory device according to claim 13, further comprising a calculation circuit configured to determine information stored in each of the memory elements that are read from a conductance value of one of the switches, the value of the voltage V_{R} and the values of the currents flowing in the source lines.
